(19) United States
(12) Patent Application Publication
(10) Pub. No.: US 2019/0177845 A1
(43) Pub. Date: Jun. 13, 2019

(54) Semiconductor Process Chamber

(71) Applicants: Samsung Electronics Co., Ltd., Suwon-si (KR); Tokyo Electron Limited, Tokyo (JP)

(72) Inventors: Seung Jae Baek, Seoul (KR); Hyun Namkoong, Seoul (KR); Tae Jong Lee, Hwaseong-si (KR); Sun Jung Kim, Suwon-si (KR); Ju Yeon Kim, Seongnam-si (KR); Noriaki Fukiage, Tokyo (JP); Masahide Iwasaki, Tokyo (JP); Yuta Sorita, Tokyo (JP)

(21) Appl. No.: 16/039,565

(22) Filed: Jul. 19, 2018

(30) Foreign Application Priority Data
Dec. 12, 2017 (KR) 10-2017-0170178

(51) Int. Cl. C23C 16/455; H01L 21/687; C23C 16/50; C23C 16/458

(52) U.S. Cl. CPC C23C 16/45565; H01L 21/68771; H01L 21/68742; C23C 16/4584; C23C 16/50

(57) ABSTRACT

A semiconductor process chamber is provided. The semiconductor process chamber includes a susceptor on which a plurality of wafers are disposed; a showerhead structure opposing the susceptor and disposed to be spaced apart from the susceptor; a plurality of plates opposing the susceptor and disposed to be spaced apart from the susceptor; and a blocking structure disposed between plates, among the plurality of plates, disposed adjacent to each other, wherein a distance between the showerhead structure and the susceptor is less than a distance between the plurality of plates and the susceptor, and a distance between the blocking structure and the susceptor is less than the distance between the plurality of plates and the susceptor.

### CROSS-REFERENCE TO RELATED APPLICATION

This application claims benefit of priority to Korean Patent Application No. 10-2017-0170178 filed on Dec. 12, 2017 in the Korean Intellectual Property Office, the disclosure of which is incorporated herein by reference in its entirety.

### FIELD

The present inventive concept relates to a process chamber, and in more detail, to a semiconductor process chamber simultaneously performing a deposition process and a plasma process.

### BACKGROUND

In order to increase a degree of integration in semiconductor devices without increased costs, the requirements for various material layers to form semiconductor devices have increased. For example, it is necessary to form a thinner material layer having uniform characteristics for a shorter period of time. Among material layers used in semiconductor devices, material layers formed using various process chambers, having been separated from each other, have been present. For example, a SiN material may be formed using a deposition process chamber and a plasma process chamber, having been separated from each other. As such, there is a limitation in reducing the time required to form material layers using various process chambers, separated from each other.

### SUMMARY

An aspect of the present inventive concept is to provide a semiconductor process chamber capable of producing a deposition layer having an improved quality.

Another aspect of the present inventive concept is to provide a semiconductor process chamber having increased productivity.

According to an aspect of the present inventive concept, provided is a semiconductor process chamber including a susceptor, a showerhead structure, a first plate, a second plate and a blocking structure, wherein the susceptor comprises a plurality of wafer zones, wherein the showerhead structure, the first plate, the second plate and the first blocking structure are disposed opposite to the susceptor and spaced apart from the susceptor, wherein a distance between the showerhead structure and the susceptor is less than a distance between the first plate and the second plate and the susceptor, and wherein a distance between the first blocking structure and the susceptor is less than the distance between the first plate and the second plate and the susceptor.

According to another aspect of the present inventive concept, provided is a semiconductor process chamber including a susceptor, a showerhead structure, a plurality of plates, and a blocking structure disposed between plates, among the plurality of plates, disposed adjacent to each other, wherein the susceptor comprises a plurality of wafer zones, wherein the showerhead structure, the plurality of plates are disposed to be spaced apart from the susceptor wherein a distance between the showerhead structure and the susceptor is less than a distance between the plurality of plates and the susceptor, and wherein a distance between the blocking structure and the susceptor is less than the distance between the plurality of plates and the susceptor.

According to another aspect of the present inventive concept, provided is a semiconductor process chamber including a susceptor, a showerhead structure, on a deposition process region of the susceptor, a first plate on a first plasma process region of the susceptor, a second plate on a second plasma process region of the susceptor, and a first blocking structure disposed between the first plasma process region and the second plasma process region and disposed to be spaced apart from the susceptor, wherein the susceptor comprises a plurality of wafer zones, wherein a distance between the showerhead structure and the susceptor is less than a distance between the first plate and the second plate, and the susceptor, and wherein a distance between the first blocking structure and the susceptor is less than the distance between the first plate and the second plate, and the susceptor.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic top view of a semiconductor process chamber according to an example embodiment;

FIG. 2 is a schematic perspective view of a susceptor disposed in a semiconductor process chamber and a structure related to the susceptor;

FIGS. 3 to 5 are schematic cross-sectional views of a semiconductor process chamber according to an example embodiment;

FIG. 6 is a schematic top view of a modified example of a semiconductor process chamber according to an example embodiment;

FIG. 7 is a schematic top view of a modified example of a semiconductor process chamber according to an example embodiment; and

FIG. 8 is a schematic top view of a modified example of a semiconductor process chamber according to an example embodiment.

### DETAILED DESCRIPTION

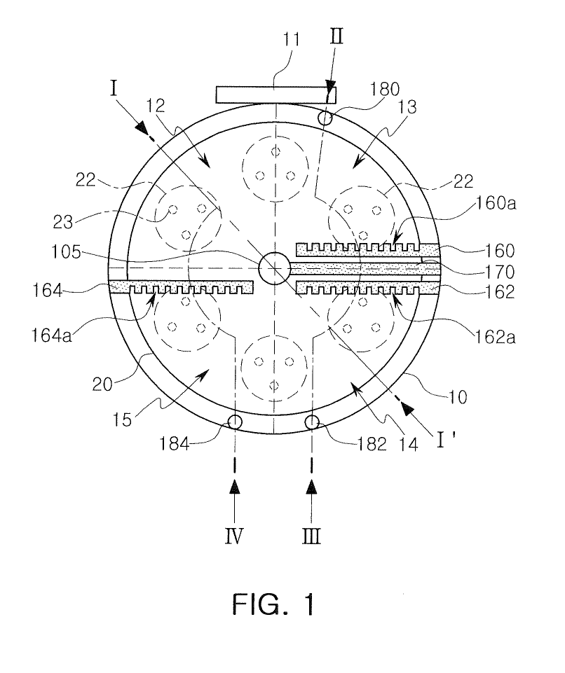

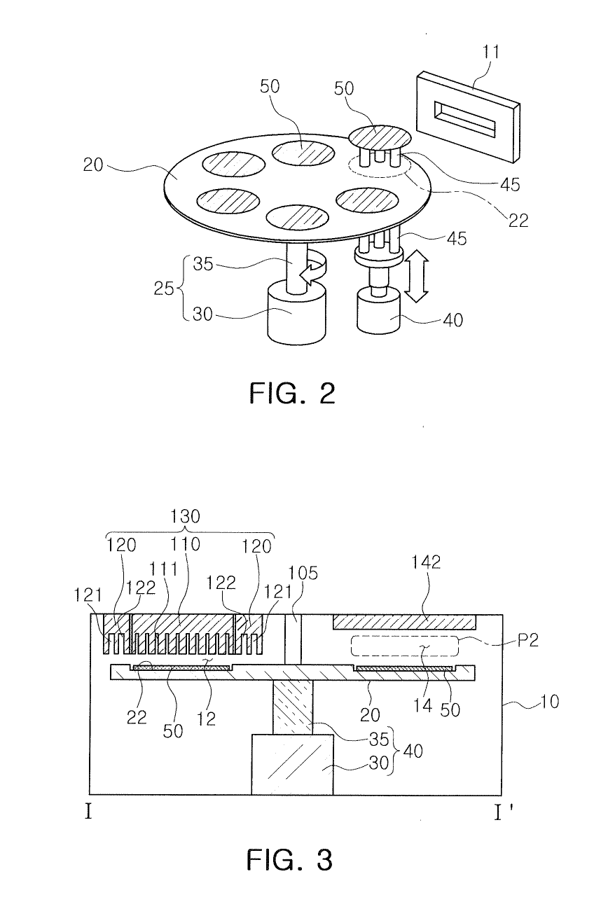

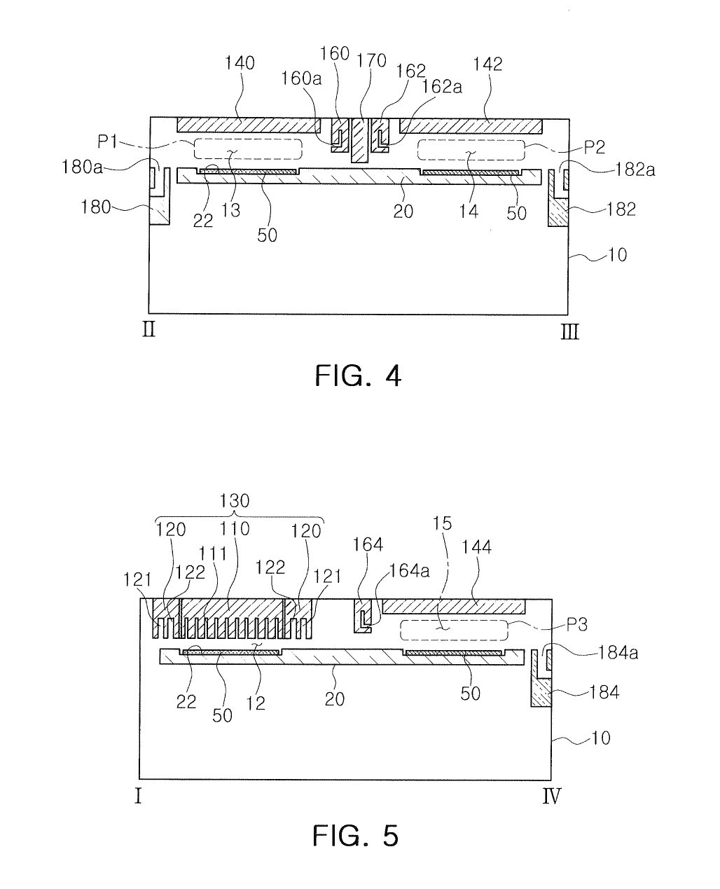

A semiconductor process chamber according to an example embodiment will be described with reference to FIGS. 1 to 5. FIG. 1 is a schematic top view of a semiconductor process chamber 10 according to an example embodiment, FIG. 2 is a schematic perspective view of a susceptor 20 disposed in the semiconductor process chamber 10 and a structure related to the susceptor 20, and FIGS. 3 to 5 are schematic cross-sectional views of a portion of the semiconductor process chamber 10 according to an example embodiment. In FIGS. 3 to 5, FIG. 3 is a schematic, cross-sectional view taken along line I-I′ from a first process region 12 to a third process region 14 of a semiconductor process chamber 10 according to an example embodiment; FIG. 4 is a schematic, cross-sectional view taken along line II-III from a second process region 13 to the third process region 14 of the semiconductor process chamber 10 according to an example embodiment; and FIG. 5 is a schematic, cross-sectional view taken along line I-IV from the first process region 12 to the third process region 14 of the semiconductor process chamber 10 according to an example embodiment.

First, with reference to FIG. 1, the semiconductor process chamber 10 may include a plurality of process regions. The plurality of process regions may include the first process region 12, the second process region 13, the third process region 14, and the fourth process region 15. The first process region 12 may be provided as a chemical vapor deposition region in which a chemical vapor deposition process may be performed without plasma. At least one or an entirety of the second process region 13, the third process region 14, and the fourth process region 15 may be provided as plasma process regions performing a process using plasma.

Hereinafter, descriptions will be provided such that the first process region 12 is substituted with the term ‘a deposition process region’, the second process region 13 is substituted with the term ‘a first plasma process region’, and the third process region 14 is substituted with ‘a second plasma process region’, and the fourth process region 15 is substituted with ‘a third plasma process region’.

Due to term substitution described above, the present inventive concept is not limited to a semiconductor process chamber, according to an example embodiment, including a single deposition process region and three plasma process regions. For example, the present inventive concept may also include a semiconductor process chamber including a plurality of deposition process regions and a plurality of plasma process regions.

With reference to FIG. 2 together with FIG. 1, the semiconductor process chamber 10 may include a susceptor 20 and a support structure 25 supporting the susceptor 20 and rotating the susceptor 20.

The support structure 25 may include a support shaft 35 supporting the susceptor 20 and a driving portion 30 disposed below the support shaft 35 and rotating the susceptor 20 by rotating the support shaft 35.

The semiconductor process chamber 10 may include a wafer lifter 40 disposed below the susceptor 20 and lifter pins 45 connected to the wafer lifter 40. The wafer lifter 40 may move the lifter pins 45 up and down.

The susceptor 20 may include a plurality of wafer zones 22. The wafer zone 22 may be provided as a region in which a wafer 50 is disposed to perform a semiconductor process.

In an example embodiment, the wafer zone 22 may be recessed from a surface of the susceptor 20.

The susceptor 20 may include pin holes 23 penetrating through the wafer zone 22.

A gate 11 through which the wafer 50 may enter and exit the semiconductor process chamber 10 may be disposed on a side of the semiconductor process chamber 10.

The wafer 50 may be lifted from the wafer zone 22 of the susceptor 20 above the susceptor 20 or may be lowered from above the susceptor 20 to the wafer zone 22 of the susceptor 20 by the lifter pins 45 penetrating through the pin holes 23. The wafer 50 having penetrated through the gate 11 to be moved above the susceptor 20 may be supported by the lifter pins 45 connected to the wafer lifter 40 and may be lowered to be mounted on a wafer mounting portion of the susceptor 20. The wafer 50 in which the semiconductor process has been completed may be lifted above the susceptor 20 by the lifter pins 55 of the wafer lifter 40 to be moved out of the semiconductor process chamber through the gate 11.

With reference to FIGS. 3 to 5, together with FIGS. 1 and 2, the semiconductor process chamber 10 may include a showerhead structure (130 of FIGS. 3 and 5), a first plate (140 of FIG. 4), a second plate (142 of FIGS. 3 and 4), and a third plate (144 of FIG. 5), disposed above the susceptor 20. The semiconductor process chamber 10 may include a first blocking structure 170 disposed above the susceptor 20. The semiconductor process chamber 10 may include a plurality of injectors 160, 162, and 164.

The showerhead structure (130 of FIGS. 3 and 5) may be disposed above a deposition process region (12 of FIGS. 3 and 5) above the susceptor 20. The showerhead structure (130 of FIGS. 3 and 5) may be disposed opposite to the susceptor and be spaced apart therefrom. The deposition process region (12 of FIGS. 3 and 5) may be defined as being disposed between the showerhead structure (130 of FIGS. 3 and 5) and the susceptor 20.

The showerhead structure (130 of FIGS. 3 and 5) may include a showerhead portion 110 including injection holes 111 injecting a process gas into the deposition process region (12 of FIGS. 3 and 5) and an edge portion 120 disposed adjacent to a showerhead portion 110.

In an example embodiment, the edge portion 120 may surround the showerhead portion 110.

The deposition process region (12 of FIGS. 3 and 5) may be formed between the showerhead portion 110 and the susceptor 20. Therefore, in a case in which the susceptor 20 is rotated to perform the semiconductor process, a first process may be performed while the wafer 50 on the wafer zone 22 of the susceptor 20 passes below the deposition process region 12.

The edge portion 120 may include an edge hole 121 injecting an inert gas and an exhaust hole 122 discharging a process gas and an inert gas outwardly of the semiconductor process chamber 10. The exhaust hole 122 may be provided as a vacuum hole. The inert gas may be provided as a purge gas. The exhaust hole 122 may be disposed closer to the showerhead portion 110 than is the edge hole 121.

The edge hole 121 and the exhaust hole 122 in the edge portion 120 may play a role in separating the deposition process region 12 from the first plasma process region 13, the second plasma process region 14, and the third plasma process region 15 or blocking the deposition process region 12. For example, the inert gas may be injected from the edge hole 121, and the inert gas in the exhaust hole 122 and the process gas in the deposition process region 12 may be intaken, thereby preventing the process gas in the deposition process region 12 from being introduced to the first plasma process region 13, the second plasma process region 14, and the third plasma process region 15 in the semiconductor process chamber 10. In addition, the edge hole 121 and the exhaust hole 122 in the edge portion 120 may block the process gases in the first plasma process region 13, the second plasma process region 14, and the third plasma process region 15 or prevent the first plasma process region 13, the second plasma process region 14, and the third plasma process region 15 from being introduced to the deposition process region 12.

In an example embodiment, a central blocking structure (105 of FIG. 3) may be disposed in a central portion of the susceptor 20. The central blocking structure (105 of FIG. 3) may prevent the process gases in the deposition process region 12, the first plasma process region 13, the second plasma process region 14, and the third plasma process region 15 from being combined with each other above the central portion of the susceptor 20.

The first plate (140 of FIG. 4) may be disposed above the first plasma process region (13 of FIG. 4) above the susceptor 20. The first plate (140 of FIG. 4) may be disposed opposite to the susceptor 20 and be spaced apart therefrom. The first plasma process region (13 of FIG. 4) may be defined as being disposed between the first plate (140 of FIG. 4) and the susceptor 20.

In a case in which the susceptor 20 is rotated to perform the semiconductor process, the wafer 50 above the wafer zone 22 of the susceptor 20 may pass below the deposition process region 12 and then, may pass below the first plasma process region 13.

In a case in which the semiconductor process is performed, a first plasma region P1 may be formed in the first plasma process region (13 of FIG. 4). Therefore, the first plasma process region (13 of FIG. 4) may be provided as a plasma process region performing a process using plasma.

The second plate (142 of FIGS. 3 and 4) may be disposed above the second plasma process region (14 of FIGS. 3 and 4) above the susceptor 20. The second plate (142 of FIGS. 3 and 4) may be disposed opposite to the susceptor and be spaced apart therefrom. The second plasma process region (14 of FIGS. 3 and 4) may be defined as being disposed between the second plate (142 of FIGS. 3 and 4) and the susceptor 20.

In a case in which the susceptor 20 is rotated to perform, the semiconductor process, the wafer 50 above the wafer zone 22 of the susceptor 20 may pass below the first plasma process region (13 of FIG. 4), and then, may pass below the second plasma process region (14 of FIGS. 3 and 4).

In a case in which the semiconductor process is performed, a second plasma region P2 may be formed in the second plasma process region (14 of FIGS. 3 and 4). Therefore, the second plasma process region (14 of FIGS. 3 and 4) may be provided as a plasma process region performing a process using plasma.

The third plate (144 of FIG. 5) may be disposed above the third plasma process region (15 of FIG. 5) above the susceptor 20. The third plate (144 of FIG. 5) may be disposed opposite to the susceptor 20 and be spaced apart therefrom. The third plasma process region (15 of FIG. 5) may be defined as being disposed between the third plate (144 of FIG. 5) and the susceptor 20.

In a case in which the susceptor 20 is rotated to perform the semiconductor process, the wafer 50 above the wafer zone 22 of the susceptor 20 may pass below the second plasma process region (14 of FIGS. 3 and 4), and then, may pass below the third plasma process region (15 of FIG. 5).

In a case in which the semiconductor process is performed, a third plasma region P3 may be formed in the third plasma process region (15 of FIG. 5). Therefore, the third plasma process region (15 of FIG. 5) may be provided as a plasma process region performing a process using plasma.

Injectors 160, 162, and 164 may include a first injector (160 of FIG. 4) supplying the process gas to the first plasma process region (13 of FIG. 4), a second injector (162 of FIG. 4) supplying the process gas to the second plasma process region (14 of FIG. 4), and a third injector (164 of FIG. 5) supplying the process gas to the third plasma process region (15 of FIG. 5).

The first injector (160 of FIG. 4) may include a first nozzle (160a of FIG. 4) for injecting the process gas into the first plasma process region (13 of FIG. 4). The first nozzle (160a of FIG. 4) may be disposed in a direction of the first plasma process region (13 of FIG. 4) and may be disposed closer to the susceptor 20 than is the first plate (140 of FIG. 4). A lower end portion of the first injector (160 of FIG. 4) may be disposed closer to the susceptor 20 than is the first plate (140 of FIG. 4) and may be disposed to be spaced apart from the susceptor 20.

The second injector (162 of FIG. 4) may include a second nozzle (162a of FIG. 4) for injecting the process gas into the second plasma process region (14 of FIG. 4). The second nozzle (162a of FIG. 4) may be disposed in a direction of the second plasma process region (14 of FIG. 4) and may be disposed closer to the susceptor 20 than is the second plate (142 of FIG. 4). A lower end portion of the second injector (162 of FIG. 4) may be disposed closer to the susceptor 20 than is the second plate (142 of FIG. 4) and may be disposed to be spaced apart from the susceptor 20.

The third injector (164 of FIG. 5) may include a third nozzle (164a of FIG. 5) for injecting the process gas into the third plasma process region (15 of FIG. 5).

The third nozzle (164a of FIG. 5) may be disposed in a direction of the third plasma process region (15 of FIG. 5) and may be disposed closer to the susceptor 20 than is the third plate (144 of FIG. 5). A lower end portion of the third injector (164 of FIG. 5) may be closer to the susceptor 20 than is the third plate (144 of FIG. 5) and may be disposed to be spaced apart from the susceptor 20.

The first nozzle 160a, the second nozzle 162a, and the third nozzle 164a may be disposed closer to the susceptor 20 than are the first plate 140, the second plate 142, and the third plate 144.

The first blocking structure (170 of FIGS. 1 and 4) may be disposed between the first plate 140 and the second plate 142 and may be disposed to be spaced apart from the susceptor 20. The first blocking structure (170 of FIGS. 1 and 4) may be disposed between the first plasma process region (13 of FIG. 4) and the second plasma process region (14 of FIG. 4).

The first blocking structure (170 of FIG. 4) may prevent the process gas in the first plasma process region (13 of FIG. 4) from flowing into the second plasma process region (14 of FIG. 4) and prevent the process gas in the second plasma process region (14 of FIG. 4) from flowing into the first plasma process region (13 of FIG. 4). Thus, the first blocking structure (170 of FIG. 4) may enhance separation of the first plasma process region (13 of FIG. 4) and the second plasma process region (14 of FIG. 4).

In an example embodiment, the first blocking structure (170 of FIGS. 1 and 4) may be disposed between the first injector (160 of FIGS. 1 and 4) and the second injector (162 of FIGS. 1 and 4).

In an example embodiment, the first injector (160 of FIGS. 1 and 4), the first blocking structure (170 of FIGS. 1 and 4), and the second injector (162 of FIGS. 1 and 4) may be disposed between the first plasma process region 13 and the second plasma process region 14. Hereinafter, the first injector (160 of FIGS. 1 and 4) may include the first nozzle 160a directed toward the first plasma process region 13, while the second injector (162 of FIGS. 1 and 4) may include the second nozzle 162a directed toward the second plasma process region 14.

The semiconductor process chamber 10 may include a plurality of exhaust ports 180, 184, and 186, disposed outwardly of the susceptor 20. The plurality of exhaust ports 180, 184, and 186 may include a first exhaust port (180 of FIGS. 1 and 4), a second exhaust port (182 of FIGS. 1 and 4), and a third exhaust port 184.

The first exhaust port (180 of FIGS. 1 and 4) may include an exhaust hole 180a for discharging the process gas in the first plasma process region 13, the second exhaust port (182 of FIGS. 1 and 4) may include an exhaust hole 182a for discharging the process gas in the second plasma process region 14, and the third exhaust port 184 may include an exhaust hole 184a for discharging the process gas in the third plasma process region 15.

The first exhaust port (180 of FIGS. 1 and 4) may be disposed in a position closer to the first plasma process region 13 than the second plasma process region 14 and the third plasma process region 15 and distant from the first injector 160 to a maximal extent.

The second exhaust port (182 of FIGS. 1 and 4) may be disposed in a position closer to the second plasma process region 14 than the first plasma process region 13 and the third plasma process region 15 and distant from the second injector 162 to a maximal extent.

The third exhaust port 184 may be disposed in a position closer to the third plasma process region 15 than the first plasma process region 13 and the second plasma process region 14 and distant from the third injector 164 to a maximal extent.

The first exhaust port 180, the second exhaust port 182, and the third exhaust port 184 may prevent the process gases injected from the first injector 160, the second injector 162, and the third injector 164 from moving into other plasma process regions.

The second exhaust port 182 and the third exhaust port 184 may be disposed adjacent to each other, thereby preventing the process gas injected from the second nozzle 162a of the second injector 162 from flowing into the third plasma process region 15 and preventing the process gas injected from the third nozzle 164a of the third injector 164 from flowing into the second plasma process region 14.

A distance between the first plate 140 and the susceptor 20, a distance between the second plate 142 and the susceptor 20, and a distance between the third plate 144 and the susceptor 20 may be equal. A distance between the first blocking structure 170 and the susceptor 20 may be less than a distance between first, second, and third injectors 160, 162, and 164 and the susceptor 20. A distance between the showerhead structure 130 and the susceptor 20 may be less than a distance between first, second, and third plates 140, 142, and 144 and the susceptor 20.

As such, the showerhead structure 130 may be disposed closer to the susceptor 20 than are the first plate 140, the second plate 142, and the third plate 144 and may include the edge portion 120 described above. The showerhead structure 130 may prevent the process gas in the deposition process region 12 from flowing into the first plasma process region 13, the second plasma process region 14, and the third plasma process region 15 and prevent the process gas in the first plasma process region 13, the second plasma process region 14, and the third plasma process region 15 from flowing into the deposition process region 12.

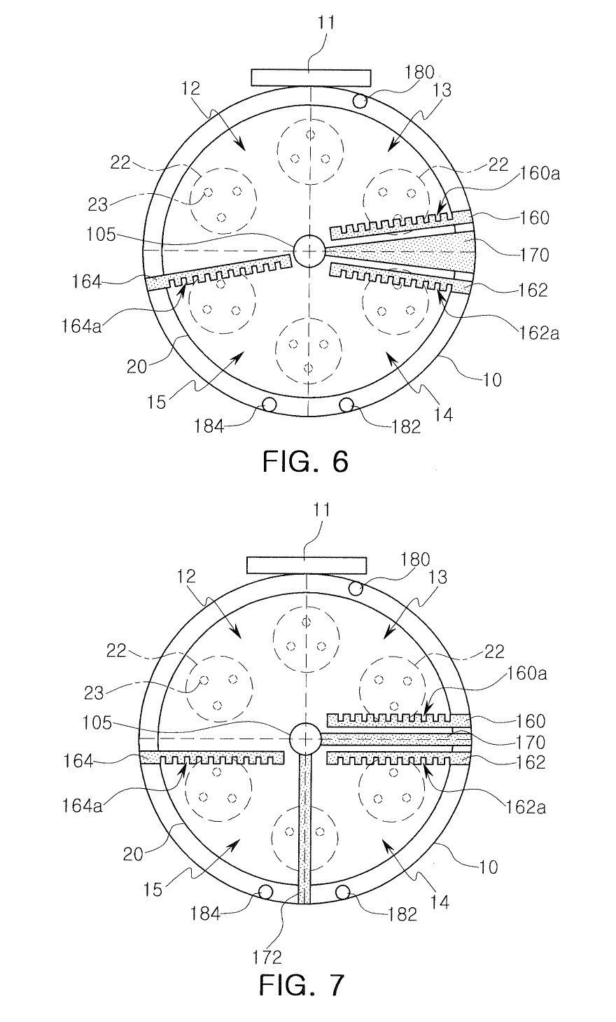

As illustrated in FIG. 1, the first blocking structure 170 may have a line pattern having a predetermined width. However, the present inventive concept is not limited thereto. For example, as illustrated in the top view of FIG. 6, the first blocking structure 170 may have a form in which a width is increased in a direction from a central portion of the susceptor 20 to an external surface.

As illustrated in FIG. 1, the first injector 160 and the second injector 162 may be parallel to each other. However, the present inventive concept is not limited thereto. For example, the first injector 160 and the second injector 162 may be modified such that they are not parallel to each other, as illustrated in FIG. 6. For example, as illustrated in FIG. 6, the first injector 160 and the second injector 162 may be disposed to be closer to each other in a direction of the central portion of the susceptor 20.

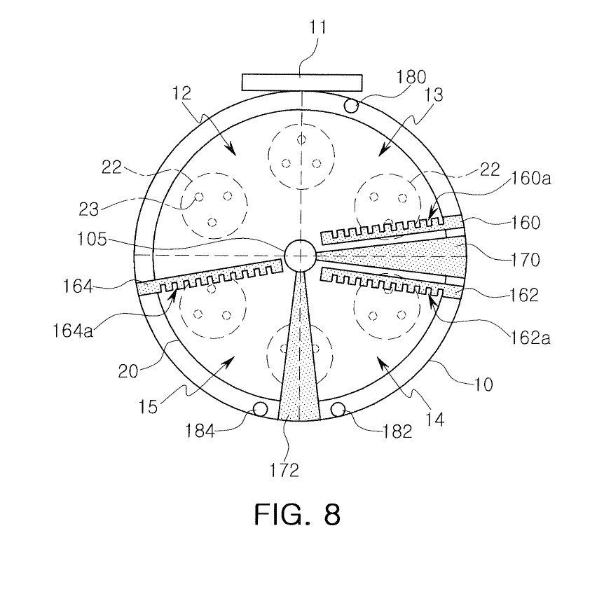

According to example embodiments described above, the first blocking structure 170 may be disposed between the first plasma process region 13 and the second plasma process region 14, while a separate blocking structure may not be disposed between the second plasma process region 14 and the third plasma process region 15. However, the present inventive concept is not limited thereto. For example, as illustrated in FIG. 7, the first blocking structure 170 may be disposed between the first plasma process region 13 and the second plasma process region 14, while a second blocking structure 172 having a structure the same as that of the first blocking structure 170 may be disposed between the second plasma process region 14 and the third plasma process region 15. The first blocking structure 170 and the second blocking structure 172 in FIG. 7 may be modified to have a form in which a width is increased in a direction from the central portion of the susceptor 20 to the external surface, as illustrated in FIG. 8.

The semiconductor process chamber 10 may form various materials required in a semiconductor device to have a high quality in a relatively short period of time. For example, a plurality of wafers 50 may be simultaneously loaded into the susceptor 20 in a single semiconductor process chamber 10. As such, a plurality of semiconductor processes may be performed to a plurality of wafers 50. For example, forming a high quality silicon nitride layer having a relatively low impurity content may include depositing silicon on the wafer 50 in the deposition process region 12, performing a nitriding process using plasma in one or two of the first plasma process region 13, the second plasma process region 14, and the third plasma process region 15, and performing a hydrogen plasma treatment process to remove impurities in nitrided silicon from the remainder of plasma process regions, which are repeated. Alternatively, forming silicon oxynitride (SiON) may include depositing silicon on the wafer 50 in the deposition process region 12, performing a plasma oxidation process in one of the first plasma process region 13 and the second plasma process region 14, performing a plasma nitridation process in the other, and performing the hydrogen plasma treatment process to remove impurities in silicon oxynitride (SiON) from the third plasma process region 15, which are repeated.

As described above, the deposition process region 12, the first plasma process region 13, the second plasma process region 14, and the third plasma process region 15 may not be affected by the process gas in other process regions disposed adjacent to each other due to the edge portion 120 of the showerhead structure 130, blocking structures 170 and 172, and exhaust ports 180, 182, and 184. Therefore, the edge portion 120 of the showerhead structure 130, the blocking structures 170 and 172, and the exhaust ports 180, 182, and 184 may strengthen independence of semiconductor processes performed in the deposition process region 12, the first plasma process region 13, the second plasma process region 14, and the third plasma process region 15. Therefore, a higher quality material may be manufactured in the semiconductor process chamber 10 more quickly.

As set forth above, according to example embodiments of the present inventive concept, a semiconductor process chamber simultaneously performing a deposition process and a plurality of plasma processes in a single process chamber may be provided. Thus, an amount of time required for a semiconductor process may be reduced. According to example embodiments of the present inventive concept, since independence of semiconductor processes performed in a deposition process region and plasma process regions may be strengthened, a higher quality material may be formed in a single semiconductor process chamber.

While example embodiments have been shown and described above, it will be apparent to those skilled in the art that modifications and variations could be made without departing from the scope of the present inventive concept as defined by the appended claims.

What is claimed is:

1. A semiconductor process chamber, comprising:
a susceptor;
a showerhead structure;
a first plate;
a second plate; and
a first blocking structure disposed between the first plate and the second plate,
wherein the susceptor comprises a plurality of wafer zones,
wherein the showerhead structure, the first plate, the second plate and the first blocking structure are disposed opposite to the susceptor and spaced apart from the susceptor,
wherein a distance between the showerhead structure and the susceptor is less than a distance between the first plate and the susceptor, and a distance between the second plate and the susceptor, and
wherein a distance between the first blocking structure and the susceptor is less than the distance between the first plate and the susceptor, and the distance between the second plate and the susceptor.

2. The semiconductor process chamber of claim 1, further comprising:
a first injector, wherein the first injector supplies a process gas to an interior of a first plasma process region between the first plate and the susceptor; and
a second injector, wherein the second injector supplies the process gas to an interior of a second plasma process region between the second plate and the susceptor.

3. The semiconductor process chamber of claim 2, wherein the first injector and the second injector are spaced apart from the susceptor.

4. The semiconductor process chamber of claim 2, wherein the first injector and the second injector each comprise a process gas injection nozzle.

5. The semiconductor process chamber of claim 4, wherein a distance between the process gas injection nozzle of the first injector and the susceptor, and a distance between the process gas injection nozzle of the second injector and the susceptor are each less than a distance between the first plate and the susceptor, and a distance between the second plate and the susceptor.

6. The semiconductor process chamber of claim 2, wherein the first blocking structure is disposed between the first injector and the second injector.

7. The semiconductor process chamber of claim 2, wherein the distance between the first blocking structure and the susceptor is less than a distance between the first injector and the susceptor, and a distance between the second injector and the susceptor.

8. The semiconductor process chamber of claim 1, further comprising a third plate disposed opposite to the susceptor and spaced apart from the susceptor.

9. The semiconductor process chamber of claim 8, wherein a first plasma process region is disposed between the first plate and the susceptor,
wherein a second plasma process region is disposed between the second plate and the susceptor,
wherein a third plasma process region is disposed between the third plate and the susceptor, and
wherein a deposition process region is disposed between the showerhead structure and the susceptor.

10. The semiconductor process chamber of claim 9, wherein the first blocking structure is disposed between the first plasma process region and the second plasma process region.

11. The semiconductor process chamber of claim 9, further comprising a second blocking structure between the second plasma process region and the third plasma process region.

12. A semiconductor process chamber, comprising:
a susceptor;
a showerhead structure;
a plurality of plates; and
a blocking structure disposed between plates, among the plurality of plates, disposed adjacent to each other,
wherein the susceptor comprises a plurality of wafer zones,
wherein the showerhead structure and the plurality of plates are disposed opposite the susceptor and spaced apart from the susceptor,
wherein a distance between the showerhead structure and the susceptor is less than a distance between the plurality of plates and the susceptor, and
wherein a distance between the blocking structure and the susceptor is less than the distance between the plurality of plates and the susceptor.

13. The semiconductor process chamber of claim 12, further comprising a support structure, wherein the support structure supports and rotates the susceptor.

14. The semiconductor process chamber of claim 12, further comprising a central blocking structure disposed in a central portion of the susceptor.

15. The semiconductor process chamber of claim 12, further comprising:
a plurality of plasma process regions disposed between the susceptor and the plurality of plates; and
a deposition process region disposed between the susceptor and the showerhead structure.

16. A semiconductor process chamber, comprising:
a susceptor;
a showerhead structure on a deposition process region of the susceptor;
a first plate on a first plasma process region of the susceptor;
a second plate on a second plasma process region of the susceptor; and
a first blocking structure disposed between the first plasma process region and the second plasma process region and disposed to be spaced apart from the susceptor,
wherein the susceptor comprises a plurality of wafer zones,
wherein a distance between the showerhead structure and the susceptor is less than a distance between the first plate and the second plate, and the susceptor, and
wherein a distance between the first blocking structure and the susceptor is less than the distance between the first plate and the second plate, and the susceptor.

17. The semiconductor process chamber of claim 16, wherein the showerhead structure comprises a showerhead portion comprising injection holes for injecting a process gas to an interior of the deposition process region, and an edge portion disposed adjacent to the showerhead portion.

18. The semiconductor process chamber of claim 17, wherein the edge portion includes an edge hole injecting an inert gas and an exhaust hole outwardly discharging the process gas and the inert gas, and wherein a distance between the exhaust hole and the showerhead portion is less than a distance between the edge hole and the showerhead portion.

19. The semiconductor process chamber of claim 16, further comprising a first injector, wherein the first injector supplies a process gas to an interior of the first plasma process region between the first plate and the susceptor; and a second injector, wherein the second injector supplies the process gas to an interior of the second plasma process region between the second plate and the susceptor,
wherein the first injector and the second injector each comprise a process gas injection nozzle, and wherein a distance between the process gas injection nozzle of the first injector and the susceptor and a distance between the process gas injection nozzle of the second injector and the susceptor are each less than a distance between the first plate and the susceptor and a distance between the second plate and the susceptor.

20. The semiconductor process chamber of claim 19, further comprising a plurality of exhaust ports disposed outwardly of the susceptor.
